(19) United States
(12) Patent Application Publication
(10) Pub. No.: US 2024/0186455 A1
(43) Pub. Date: Jun. 6, 2024

(54) VERTICAL-TYPE LIGHT-EMITTING DIODE AND LIGHT-EMITTING DEVICE

(71) Applicant: Tianjin Sanan Optoelectronics Co., Ltd., Tianjin (CN)

(72) Inventors: Shuili YU, Tianjin (CN); Yan LI, Tianjin (CN); Chenming WU, Tianjin (CN); Si ZHANG, Tianjin (CN); Kaiqing XU, Tianjin (CN); Jinghua CHEN, Tianjin (CN); Kunte LIN, Tianjin (CN)

(73) Assignee: Tianjin Sanan Optoelectronics Co., Ltd., Tianjin (CN)

(21) Appl. No.: 18/491,814

(22) Filed: Oct. 23, 2023

(30) Foreign Application Priority Data
Dec. 2, 2022 (CN) 202211542293.7

(51) Int. Cl. H01L 33/38; H01L 33/62

(52) U.S. Cl. CPC H01L 33/382; H01L 33/62

(57) ABSTRACT

The disclosure relates to a vertical-type light-emitting diode, which includes a semiconductor stack layer, a first electrode, a second electrode and a protruding protective electrode. The semiconductor stack layer has an upper surface and a lower surface opposite to each other. The semiconductor stack layer includes a first semiconductor layer, a light-emitting layer and a second semiconductor layer stacked in sequence from the lower surface to the upper surface. The first electrode is located on the lower surface of the semiconductor stack layer and connected to the first semiconductor layer. The second electrode is located on the upper surface of the semiconductor stack layer and is connected to the second semiconductor layer, and the protruding protective electrode is connected to the second electrode. The upper surface of the protruding protective electrode is higher than the upper surface of the second electrode.

### CROSS-REFERENCE TO RELATED APPLICATION

This application claims the priority benefit of China application serial no. 202211542293.7, filed on Dec. 2, 2022. The entirety of the above-mentioned patent application is hereby incorporated by reference herein and made a part of this specification.

### BACKGROUND

### Field of the Disclosure

The disclosure relates to the technical field of semiconductor manufacturing, in particular to a vertical-type light-emitting diode and a light-emitting device.

### Description of Related Art

Light-emitting diode (LED) is a semiconductor light-emitting element, normally made of semiconductors such as GaN, GaAs, GaP, GaAsP, etc. The core of LED is a PN junction with light-emitting properties. LED has the advantages of high luminous intensity, high efficiency, small size, and long service life, and is considered to be one of the most promising light sources at present. LED has been commonly adopted in lighting, monitoring command, high-definition studio, high-end cinema, office display, conference interaction, virtual reality and other fields.

At present, in the process of preparing light-emitting diodes, blue film (or release paper) is adopted to package chips. In the process of realizing the present disclosure, the inventor found that the problems of the related art at least include the following: as shown in FIG. 1, in conventional vertical-type light-emitting diodes, since a pad electrode is the highest point of the light-emitting diode, in the blue film process, the pad electrode is in direct contact with the blue film (the blue film is indicated by dashed lines in FIG. 1), which causes the blue film to easily contaminate the pad electrode (as shown in FIG. 2, when the film is peeled off and poured, the pad electrode comes into contact with the blue film and causes dirt, that is, there is a lot of dirt on the surface of the pad electrode located in the wiring area). The dirt will cause abnormalities on the surface of the pad electrode, increase the risk of subsequent wiring, and reduce quality of chips.

It should be noted that the information disclosed in this background section is only intended to increase understanding of the general background of the present disclosure, and should not be regarded as an admission or in any way implied that the information constitutes what is already known to those of ordinary skill in the art.

### SUMMARY OF THE DISCLOSURE

The present disclosure provides a light-emitting diode, which includes a semiconductor stack layer, a first electrode, a second electrode and a protruding protective electrode.

The semiconductor stack layer has an upper surface and a lower surface opposite to each other, and the semiconductor stack layer includes a first semiconductor layer, a light-emitting layer and a second semiconductor layer stacked in sequence along the direction from the lower surface to the upper surface. The first electrode is located at the lower surface of the semiconductor stack layer and connected to the first semiconductor layer. The second electrode is located at the upper surface of the semiconductor stack layer and connected to the second semiconductor layer. The protruding protective electrode is connected to the second electrode. The upper surface of the protruding protective electrode is higher than the upper surface of the second electrode.

In some embodiments, the first distance from the upper surface of the protruding protective electrode to the upper surface of the semiconductor stack layer is greater than the second distance from the upper surface of the second electrode to the upper surface of the semiconductor stack layer.

In some embodiments, the first distance is at least 1000 angstroms greater than the second distance.

In some embodiments, the protruding protective electrode has a height ranging from 1000 angstroms to 5 microns.

In some embodiments, the material of the protruding protective electrode includes at least one selected from the group consisting of Au, Pt, Ti, Ni, Ge, Be, Zn, Al, and Cr.

In some embodiments, the second electrode includes a pad electrode and a finger electrode, and the pad electrode is connected to the finger electrode.

In some embodiments, the protruding protective electrode has a first width, the pad electrode has a second width, and the first width is less than the second width.

In some embodiments, the second width is at least 85% wider than the first width.

In some embodiments, the upper surface of the semiconductor stack layer has a groove, and the pad electrode is disposed within the groove.

In some embodiments, the depth of the groove ranges from 1000 angstroms to 5 microns.

The present disclosure also provides a light-emitting device, which adopts the light-emitting diode provided in any of the above embodiments.

A light-emitting diode and a light-emitting device provided by an embodiment of the present disclosure may form a height difference between the blue film and the second electrode for wire bonding through the setting of the protruding protective electrode, so as to avoid the contact between the second electrode and the blue film as much as possible, thereby reducing the probability of contamination on the second electrode due to contact with the blue film, and decreasing the risk of subsequent wire bonding (the dirty surface will make the bonding wire not strong enough, affecting the use of subsequent packages). In this way, it is possible to ensure optoelectronic quality of the vertical-type light-emitting diodes.

Other features and advantageous effects of the present disclosure will be set forth in the subsequent description, and some of the technical features and advantageous effects may be apparent from the description or learned by practicing the present disclosure.

### BRIEF DESCRIPTION OF THE DRAWINGS

In order to more clearly explain the embodiments of the present disclosure or the technical solutions in the related art, a brief introduction will be provided below to the drawings that need to be used in the description of the embodiments or the related art. It is clear that some of the drawings in the following description illustrate some embodiments of the present disclosure. For those of ordinary skill in the art, other drawings may be obtained based on these drawings without exerting any inventive effort.

FIG. 1 is a schematic structural diagram of a conventional vertical-type light-emitting diode.

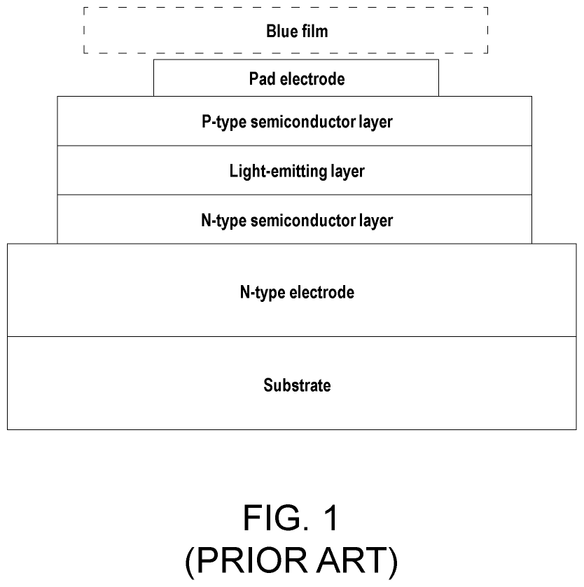

FIG. 2 is a schematic diagram of a surface of a conventional vertical-type light-emitting diode.

FIG. 3 is a schematic top view of a vertical-type light-emitting diode provided in a first embodiment of the present disclosure.

FIG. 4 is a schematic longitudinal cross-sectional view taken along line F-F of FIG. 3.

FIG. 5 is a schematic view of a surface of a vertical-type light-emitting diode of the present disclosure.

FIG. 6 to FIG. 8 are schematic structural diagrams of various stages of a manufacturing process of the vertical-type light-emitting diode shown in FIG. 4.

FIG. 9 is a schematic structural diagram of a vertical-type light-emitting diode provided in a second embodiment of the present disclosure.

### DESCRIPTION OF EMBODIMENTS

In order to make the purpose, technical solutions and advantages of the embodiments of the present disclosure clearer, the technical solutions in the embodiments of the present disclosure will be clearly and completely described below with reference to the drawings in the embodiments of the present disclosure. Clearly, the described embodiments are a part of the embodiments of the present disclosure, rather than all the embodiments; the technical features designed in different embodiments of the present disclosure described below may be combined with each other as long as they do not conflict with each other. Based on the embodiments of the present disclosure, all other embodiments obtained by those of ordinary skill in the art without creative efforts should fall within the scope of protection of the present disclosure.

In the description of the present disclosure, it should be understood that the orientations or positional relationships indicated by terms “center”, “lateral”, “upper”, “lower”, “left”, “right”, “vertical”, “horizontal”, “top”, “bottom”, “inner”, “outer” and the like refer to the orientations or positional relationships shown in the drawings, and these terms are only for the convenience of describing the present disclosure and simplifying the description, and do not indicate or imply the device or components must have a specific orientation, or be constructed and operate in a specific orientation and are therefore should not to be construed as limitations of the disclosure. In addition, the terms “first” and “second” are used for descriptive purposes only and cannot be understood as indicating or implying relative importance or implicitly indicating the quantity of indicated technical features. Therefore, features defined as “first” and “second” may explicitly or implicitly include one or more of these features. In the description of the present disclosure, unless otherwise specified, “plurality” means two or more. In addition, the term “include” and any variations thereof mean “at least including”.

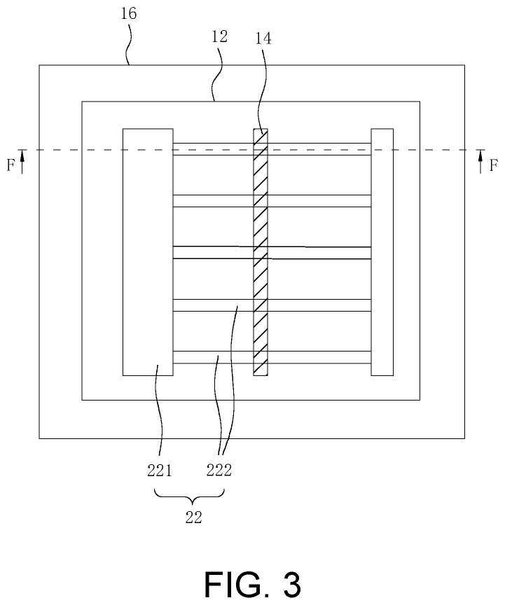

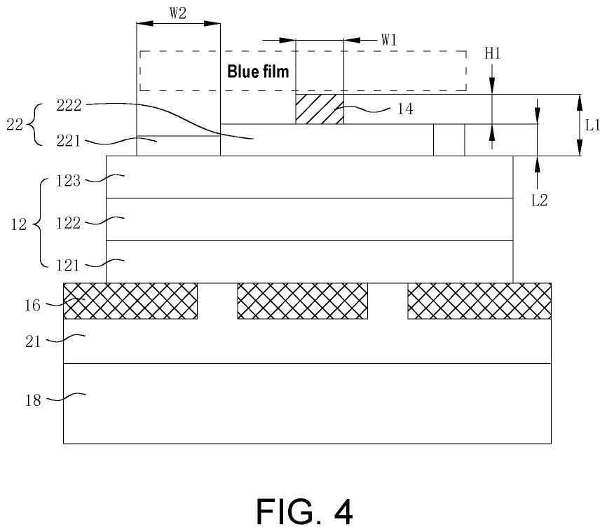

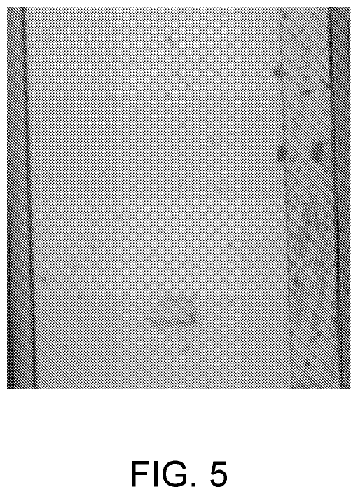

Please refer to FIG. 3, FIG. 4 and FIG. 5. FIG. 3 is a schematic top view of the structure of a vertical-type light-emitting diode provided by a first embodiment of the present disclosure. FIG. 4 is a schematic longitudinal cross-sectional view taken along line F-F of FIG. 3. FIG. 5 is a schematic view of a surface of a vertical-type light-emitting diode of the present disclosure. The first embodiment of the present disclosure provides a vertical-type light-emitting diode. As shown in the figure, the vertical-type light-emitting diode may include a semiconductor stack layer 12, a first electrode 21, a second electrode 22, and a protruding protective electrode 14.

The semiconductor stack layer 12 has an upper surface and a lower surface opposite to each other, and the semiconductor stack layer 12 includes a first semiconductor layer 121, a light-emitting layer 122 and a second semiconductor layer 123 stacked in sequence along the direction from the lower surface to the upper surface.

The first semiconductor layer 121 may be an N-type semiconductor layer, and is able to provide electrons to the light-emitting layer 122 under the action of a power source. In some embodiments, the first semiconductor layer 121 includes an N-type doped nitride layer, an arsenide layer and a phosphide layer. The N-type doped nitride layer, arsenide layer and phosphide layer may include one or more N-type impurities of Group IV elements. The N-type impurities may include one of Si, Ge, Sn or a combination thereof.

The light-emitting layer 122 may have a quantum well (QW for short) structure. In some embodiments, the light-emitting layer 122 may also be a multiple quantum well (referred to as MQW) structure, where the multiple quantum well structure includes a plurality of quantum well layers and a plurality of quantum barrier layers arranged alternately in a repeated manner, and may be a multi-quantum well structure, such as GaN/AlGaN, InAlGaN/InAlGaN, InGaN/AlGaN, InGaP/AlGaInP, AlGaInP/AlGaInP or InGaAs/AlGaAs. In addition, the composition and thickness of the well layer within the light-emitting layer 122 determine the wavelength of the generated light. In order to improve the luminous efficiency of the light-emitting layer 122, the purpose may be achieved by changing the depth of the quantum wells, the number, thickness and/or other characteristics of the paired quantum well layers and quantum barrier layers in the light-emitting layer 122.

The second semiconductor layer 123 may be a P-type semiconductor layer, and is able to provide holes to the light-emitting layer 122 under the action of a power supply. In some embodiments, the second semiconductor layer 123 includes a P-type doped nitride layer, an arsenide layer and a phosphide layer. The P-type doped nitride layer, arsenide layer and phosphide layer may include one or more P-type impurities of Group II elements. The P-type impurities may include one of Mg, Zn, Be or a combination thereof. The second semiconductor layer 123 may be a single-layer structure or a multi-layer structure with different compositions. In addition, the setting of the epitaxial structure is not limited thereto, and other types of epitaxial structures may be selected according to actual needs.

The first electrode 21 is located at the lower surface of the semiconductor stack layer 12 and connected to the first semiconductor layer 121. The first electrode 21 may have a single-layer, double-layer or multi-layer structure, such as a stacked structure like Ti/Al, Ti/Al/Ti/Au, Ti/Al/Ni/Au, V/Al/Pt/Au, etc.

The second electrode 22 is located at the upper surface of the semiconductor stack layer 12 and connected to the second semiconductor layer 123. The second electrode 22 may be made of a transparent conductive material, or a metal material, which may be adaptively selected according to the doping condition of the surface layer of the second semiconductor layer 123 (such as the P-type AlGaInP surface layer). In some embodiments, the second electrode 22 is made of a transparent conductive material, and the material may include indium tin oxide (ITO), indium zinc oxide (IZO), indium oxide (InO), tin oxide (SnO), cadmium tin oxide (CTO), antimony tin oxide (ATO), aluminum zinc oxide (AZO), zinc tin oxide (ZTO), gallium doped zinc oxide (GZO), tungsten doped indium oxide (IWO) or zinc oxide (ZnO), but the embodiments of the disclosure are not limited thereto.

The protruding protective electrode 14 is connected to the second electrode 22. The upper surface of the protruding protective electrode 14 is higher than the upper surface of the second electrode 22. By arranging the protruding protective electrode 14 to be higher than the second electrode 22, the protruding protective electrode 14 becomes the highest point of the light-emitting diode, so it is possible for a height difference to be formed between the blue film (the position of the blue film is indicated by the dashed lines in FIG. 4) and the second electrode 22 for wiring. In this way, it is likely to prevent the second electrode 33 from contacting the blue film as much as possible, thereby reducing the probability of the second electrode 22 becoming dirty due to contact with the blue film, and reducing the risk of subsequent wiring, while ensuring optoelectronic quality of the vertical-type light-emitting diode. The material of the protruding protective electrode 14 may include at least one selected from the group consisting of Au, Pt, Ti, Ni, Ge, Be, Zn, Al, and Cr. Regarding the preparation of the protruding protective electrode 14, it is only necessary to add a photomask process to the manufacturing process without increasing the difficulty of the process.

The comparison between the height of the upper surface of the protruding protective electrode 14 and the height of the upper surface of the second electrode 22 may be made based on the height of the upper surface of the semiconductor stack layer 12 as a reference. That is to say, the first distance L1 from the upper surface of the protruding protective electrode 14 to the upper surface of the semiconductor stack layer 12 is greater than the second distance L2 from the upper surface of the second electrode 22 to the upper surface of the semiconductor stack layer 12. Considering the protection for the electrodes for wire bonding and to avoid the contact between the electrodes for wire bonding and the blue film, it is preferable that the first distance L1 is at least 1000 angstroms larger than the second distance L2.

In some embodiments, the second electrode 22 includes a pad electrode 221 and a finger electrode 222. The pad electrode 221 is connected to the finger electrode 222 and serves as an electrode for subsequent wiring. A good ohmic contact is formed between the finger electrode 222 and the second semiconductor layer 123, and it is possible to achieve a current-spreading effect.

The protruding protective electrode 14 has a first width W1, and the pad electrode 221 has a second width W2. The first width W1 of the protruding protective electrode 14 is smaller than the second width W2 of the pad electrode 221, so as to avoid affecting the subsequent wire bonding to the pad electrode 221. Considering the convenience of wire bonding and in order not to affect the use of subsequent packages, the second width W2 is at least 85% wider than the first width W1, preferably 100%, 110%, and 120%.

Considering the protection for electrodes for wire bonding and in order to avoid the contact between the pad electrode 221 for wire bonding and the blue film, the height H1 of the protruding protective electrode 14 is set from 1000 angstroms to 5 microns. Considering the cost of using metal, it is set that the thickness of the pad electrode 221 is preferably smaller than the thickness of the finger electrode 222. Because the pad electrode 221 is mainly used for wiring, it is possible to reduce the cost and it will not affect the electrical characteristics by reducing the thickness thereof.

In some embodiments, the vertical-type light-emitting diode may further include a carrier substrate 18 and an insulating layer 16. The carrier substrate 18 is located under the first electrode 21 and mainly serves a carrying function. The insulating layer 16 is located between the semiconductor stack layer 12 and the first electrode 21 and mainly serves insulation protection and current blocking. The material of the insulating layer 16 includes a non-conductive material. The non-conductive material is preferably an inorganic material or a dielectric material. Inorganic materials may include silica gel. Dielectric materials include electrically insulating materials such as aluminum oxide, silicon nitride, silicon oxide, titanium oxide, or magnesium fluoride. For example, the insulating layer 16 may be silicon dioxide, silicon nitride, titanium oxide, tantalum oxide, niobium oxide, barium titanate or a combination thereof. The combination may be, for example, a Bragg reflector (DBR) formed by repeatedly stacking two materials with different refractive indexes.

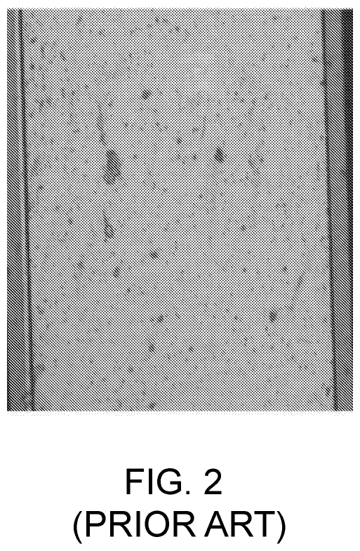

Comparing FIG. 5 with FIG. 2, it can be seen that the vertical-type light-emitting diode provided by the present disclosure may greatly reduce the contamination on the surface of the second electrode 22 in the wiring area (box illustrated with dashed lines) by adopting the setting of protruding protective electrode 14, so as to obtain a cleaner vertical-type light-emitting diode, reduce the risk of subsequent wire bonding, and ensure the optoelectronic quality of the vertical-type light-emitting diode.

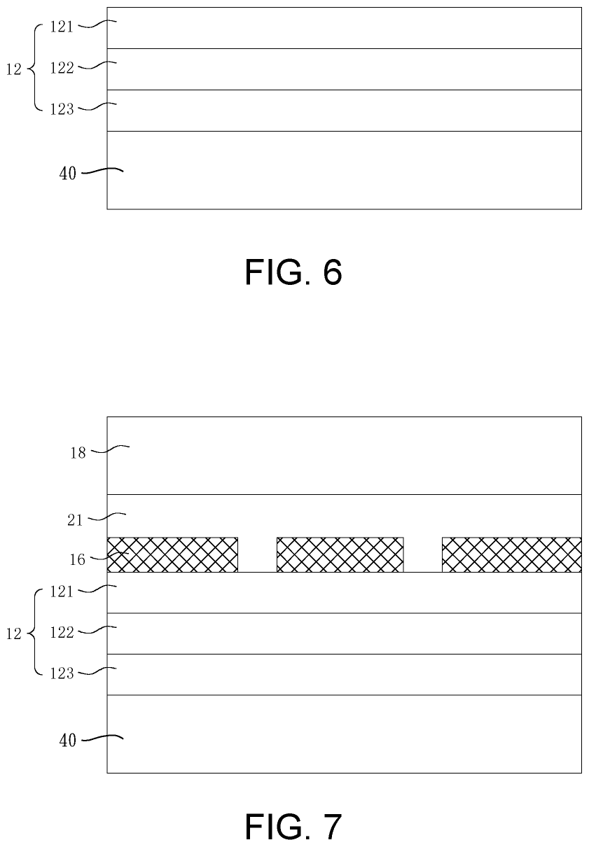

The following discloses a method for manufacturing the vertical-type light-emitting diode shown in FIG. 4. Please refer to FIG. 6 to FIG. 8. FIG. 6 to FIG. 8 are schematic structural diagrams of various stages of a manufacturing process of the vertical-type light-emitting diode shown in FIG. 4.

First, as shown in FIG. 6, a growth substrate 40 is provided. Next, the second semiconductor layer 123, the light-emitting layer 122 and the first semiconductor layer 121 are grown sequentially on the growth substrate 40.

Next, as shown in FIG. 7, an insulating layer 16 is formed on the first semiconductor layer 121, and the insulating layer 16 is etched to form an opening; then, metal is plated on the insulating layer 16 and plated on the first semiconductor layer 121 through the opening to form the first electrode 21; and then the carrier substrate 18 is disposed on the first electrode 21.

Finally, as shown in FIG. 8, the growth substrate 40 is first removed, the entire structure is turned over, and then the semiconductor stack layer 12 at the edge is etched. Then, the finger electrode 222 is first prepared on the second semiconductor layer 123; and then, the pad electrode 221 is prepared on the second semiconductor layer 123, and the protruding protective electrode 14 is prepared on the finger electrode 222 at the same time. The materials of the finger electrode 222 and the pad electrode 221 may be different. For example, the multilayer structure of the finger electrode 222 is an Au/BeAu/Au metal structure, and the multilayer structure of the pad electrode 221 is a Ti/Pt/Au metal structure.

The above is only a disclosed method for manufacturing the vertical-type light-emitting diode shown in FIG. 4. The disclosure is not limited thereto, but is only used to illustrate implementation of a preparation method of the vertical-type light-emitting diode.

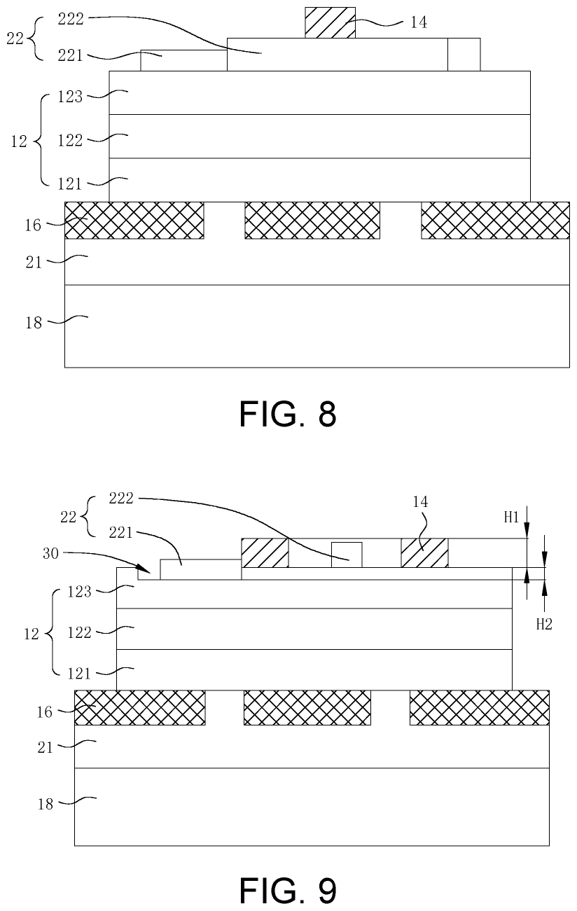

Please refer to FIG. 9. FIG. 9 is a schematic structural diagram of a vertical-type light-emitting diode provided by the second embodiment of the present disclosure. Compared with the vertical-type light-emitting diode shown in the first embodiment of FIG. 3, the vertical-type light-emitting diode provided by the second embodiment is different in that: the upper surface of the semiconductor stack layer 12 has a groove 30, which is formed by being recessed from the upper surface of the second semiconductor layer 123 toward the first semiconductor layer 121. The pad electrode 221 is disposed in the groove 30. The protruding protective electrode 14 is connected to the side wall of the pad electrode 221. Compared with the first embodiment, this method of forming the groove 30 first and then plating the second electrode 22 may save one yellowing process and metal, and reduce production costs. In addition, the number of protruding protective electrodes 14 may be multiple to achieve better protection effect.

Considering the protection for electrodes for wire bonding and in order to avoid the contact between the electrodes for wire bonding and the blue film, the depth H2 of the groove 30 is preferably in the range of 1000 angstroms to 5 microns.

The present disclosure further provides a light-emitting device, which may adopt the light-emitting diode provided in any one of the above-mentioned embodiments.

Based on the above, a light-emitting diode and a light-emitting device provided by an embodiment of the present disclosure may form a height difference between the blue film and the second electrode 22 for wire bonding through the setting of the protruding protective electrode 14, so as to avoid the contact between the second electrode 22 and the blue film as much as possible, thereby reducing the probability of contamination on the second electrode 22 due to contact with the blue film, and decreasing the risk of subsequent wire bonding. In this way, it is possible to ensure optoelectronic quality of the vertical-type light-emitting diodes.

In addition, those skilled in the art should understand that although there are many problems in the related art, each embodiment or technical solution of the present disclosure may be improved in only one or several aspects without having to simultaneously solve all of the technical problems listed in the related art or the background technology. Those skilled in the art will understand that content not mentioned in a claim shall not be construed as a limitation to the claims.

Finally, it should be noted that the above embodiments are only used to illustrate the technical solution of the present disclosure, but not to limit the disclosure. Although the present disclosure has been described in detail with reference to the foregoing embodiments, those of ordinary skill in the art should understand that: The technical solutions described in the foregoing embodiments may still be modified, or some or all of the technical features may be equivalently replaced; and these modifications or substitutions do not deviate the essence of the corresponding technical solutions from the scope of technical solutions to be protected by the embodiments of the present disclosure.

What is claimed is:

1. A vertical-type light-emitting diode, comprising:
a semiconductor stack layer having an upper surface and a lower surface opposite to each other, wherein the semiconductor stack layer comprises a first semiconductor layer, a light-emitting layer and a second semiconductor layer stacked in sequence along a direction from the lower surface to the upper surface;
a first electrode located at the lower surface of the semiconductor stack layer and connected to the first semiconductor layer;
a second electrode located at the upper surface of the semiconductor stack layer and connected to the second semiconductor layer;
a protruding protective electrode connected to the second electrode;
wherein an upper surface of the protruding protective electrode is higher than an upper surface of the second electrode.

2. The vertical-type light-emitting diode according to claim 1, wherein a first distance from the upper surface of the protruding protective electrode to the upper surface of the semiconductor stack layer is greater than a second distance from the upper surface of the second electrode to the upper surface of the semiconductor stack layer.

3. The vertical-type light-emitting diode according to claim 2, wherein the first distance is at least 1000 angstroms greater than the second distance.

4. The vertical-type light-emitting diode according to claim 1, wherein the protruding protective electrode has a height ranging from 1000 angstroms to 5 microns.

5. The vertical-type light-emitting diode according to claim 1, wherein a material of the protruding protective electrode comprises at least one selected from a group consisting of Au, Pt, Ti, Ni, Ge, Be, Zn, Al, and Cr.

6. The vertical-type light-emitting diode according to claim 1, wherein the second electrode comprises a pad electrode and a finger electrode, and the pad electrode is connected to the finger electrode.

7. The vertical-type light-emitting diode according to claim 6, wherein the protruding protective electrode has a first width, the pad electrode has a second width, and the first width is less than the second width.

8. The vertical-type light-emitting diode according to claim 7, wherein the second width is at least 85% wider than the first width.

9. The vertical-type light-emitting diode according to claim 6, wherein the upper surface of the semiconductor stack layer has a groove, and the pad electrode is disposed within the groove.

10. The vertical-type light-emitting diode according to claim 9, wherein a depth of the groove ranges from 1000 angstroms to 5 microns.

11. A light-emitting device, which adopts the vertical-type light-emitting diode according to claim 1.
